(19) United States
(12) Patent Application Publication
(10) Pub. No.: US 2005/0145488 A1
(43) Pub. Date: Jul. 7, 2005

(54) Tube magnetron

(76) Inventors: Wolfgang Erbkamm, Dresden (DE); Hans-Christian Hecht, Dresden (DE)

Correspondence Address: BAKER & BOTTS, 30 ROCKEFELLER PLAZA, NEW YORK, NY, 10112, US

(21) Appl. No.: 10/508,819

(22) PCT Filed: Mar. 24, 2003
(86) PCT No.: PCT/DE03/00962

(30) Foreign Application Priority Data
Mar. 22, 2002 (DE) 10213043.4

(51) Int. Cl. C23C 14/35

(52) U.S. Cl. 204/298.21; 204/298.22

(57) ABSTRACT

A tube magnetron for a vacuum coating applications such as plasma sputtering is provided with a hollow rotating tube target arrangement and a magnet system. The hollow rotating tube target arrangement has longitudinally extended target plates that are fixed to a target support. The target plates in cross section are arranged adjacent to each other to form a polygon. The magnet system generates a magnetic field which extends through the tube target arrangement. The magnet system is configured so that generated magnet field has in cross section two maxima arranged in the axial longitudinal direction of the tube target arrangement. The tube magnetron is configured for use with sputtering targets that are in the form of target plates. The target plates may be made from ceramics, ceramic-like and/or high-melting point materials. Materials such as ITO, zinc oxide, silicon can be efficiently and uniformly sputter coated on substrates.

### CROSS REFERENCE TO RELATED APPLICATIONS

This application claims the benefit of International Patent Application No. PCT/DE03/000962 filed Mar. 24, 2003, which claims priority to German Patent Application No. 102 13 043.4 filed Mar. 22, 2002.

### FIELD OF THE INVENTION

The invention relates to tube magnetrons. In particular, the invention relates to tube magnetrons provided with hollow rotating tube target arrangements and magnet systems, for applications in a vacuum or sputter coating processes.

### BACKGROUND OF THE INVENTION

Tube magnetrons of general type have long been known in use in vacuum coating (e.g., sputter coating) plants for coating various large-area substrates with a variety of coating materials. They are characterized by a high rate of utilization of the target material and long target life. A tube magnetron is described in German patent DE 217,964 A3. Uniform rotation of the tube target results in uniform erosion of the sputter material on the tube target surface. Here, the tube target consists entirely of the material to be sputtered, such as for example of aluminum or titanium. Target cooling, realized in the interior of the tube target, owing to the more favorable heat transfer in the tube, is substantially more effective than in flat targets, which permits an increase in output with respect to the coating rate as compared with flat targets. Full-material tube targets of copper and titanium are likewise known in use by the applicant.

An additional tube magnetron is disclosed in U.S. Pat. No. 4,356,073. Tube targets that consist of a supporting tube and a layer, coated all around, of the sputter material are used in this case. This layer consists principally of metallic sputter material and is applied chiefly by plasma spraying.

U.S. Pat. No. 4,443,318 describes a rotating magnetron equipped with a tube target, which has a plurality of individual target strips with the applied sputter material, fixed to a supporting tube. The target strips lie in individual grooves of the supporting tube and are pressed on the supporting tube by intermediary strips (claws) that are bolted to the target tube. This design permits the use of target materials produced in plate form on the surface of tube targets. This has the advantage of lower-cost and greater range of use of a variety of sputter materials because, depending upon the material, sometimes the production of plate material is simpler and more economical than the use of full-material tube targets and the plasma spray method and, in addition, sometimes only production in plate form is suitable, as for example in ceramic sputter materials with their greater hardness and brittleness.

Application of ceramic sputter material to the surface of a tube target is difficult by the plasma spray method, since the required material thickness and material homogeneity of the ceramic material compositions is not thereby obtained. Slight structural and alloy variations in certain ceramic sputter layers, such as for example in indium-zinc oxide alloy (ITO) or silicon oxide, result in process variations. Full-material tube targets of ceramic sputter material with the required properties likewise are not known in the present related art. The ceramic material sintered by the high-pressure pressing method has a high blocking density and hardness, owing to which this material cannot be processed in just any desired way. The plate form is therefore a preferred production form for ceramic sputter materials.

However, in the known tube targets covered with target plates the fact that the tangential bearing of the flat plates results in a variable radial distance of the surface of the target plates from the axis of rotation of the tube target and, in addition, owing to the supporting mechanisms of the target plates (claws) surface regions without target material occur, whereby a polygonal tube target surface with inhomogeneous sections is produced, is disadvantageous. This surface of the tube target leads, in the coating process during the operation of rotation of the tube target owing to the stationary magnetic fields, to considerable fluctuations in the magnetic field effect and hence in the sputter rate and subsequently to fluctuations in the processing parameters of the plasma. Process uniformity as an essential condition for layer quality on the substrate is upset.

Consideration is now being given to ways of improving tube magnetron designs for coating applications. In particular, attention is directed to designs of tube magnetron which lead to improved process uniformity in sputter coating applications. The tube magnetrons may be designed for a variety of sputter target materials including ceramic materials.

### SUMMARY OF THE INVENTION

In accordance with the principles of the invention, tube magnetrons are provided for vacuum coating of materials such as ceramic materials or other high melting point materials by plasma sputtering processes. The tube magnetrons are provided with hollow rotating tube target arrangements and magnet systems.

An exemplary tube target arrangement has longitudinally extending target plates, which are fixed to a target support. The longitudinally extending target plates may be configured as a polygon. An exemplary magnet system generates magnetic fields in the interior of the tube magnetron. The magnet system is configured to generate at least two magnetic field maxima in cross section arranged in the axial longitudinal direction of the tube target arrangement. The magnetic field maxima refer to the maximum of the tangentially oriented magnetic field component on the target surface.

The number and width target plates and the configuration of the magnetic field are suitably selected to minimize plasma fluctuations or sputtering rate variations across the targets. In an exemplary designs of the tube magnetron, the number and width of target plates are selected so that an angle α, which is enclosed by two imaginary radial lines each running through adjacent corners of the target plates polygon, is related to an angle β, which is enclosed by two imaginary radial lines running through the magnetic field maxima at least approximately consistent with the relation β=(n+0.5) α, where n may be any non negative integer including zero.

### BRIEF DESCRIPTION OF THE DRAWINGS

Further features of the invention, its nature, and various advantages will be more apparent from the following detailed description and the accompanying drawings, wherein like reference characters represent like elements throughout, and in which:

FIG. 1 is a cross sectional view of an exemplary tube magnetron designed in accordance with the principles of the present invention.

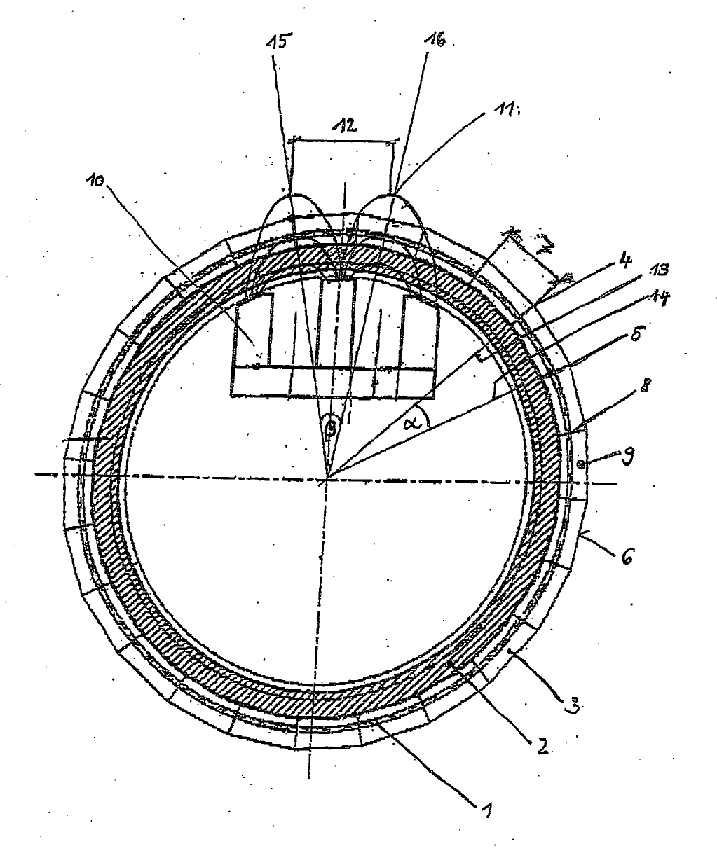

The following is a list of reference characters used in FIG. 1
1. Tube target
2. target support
3. target plate
4. polygon corner
5. polygon corner
6. polygon sink
7. width of target plate
8. longitudinal edge of target plate
9. central longitudinal axis of target plate
10. magnet system
11. magnetic field maximum
12. distance between magnetic field maxima
13. radial line through a polygon corner
14. radial line through a polygon corner
15. radial line through a magnetic field maximum
16 radial line through a magnetic field maximum

### DETAILED DESCRIPTION OF THE INVENTION

The present invention provides tube magnetron designs for coating of substrates with thin film materials. The tube magnetrons are designed for use with sputter targets made of materials (e.g., ceramic materials and high melting-point material) which are difficult to sputter coat using conventional tube magnetrons or other conventional sputtering arrangements.

The inventive tube magnetrons are configured to use sputtering target material which may be in the form of target plates disposed on tube target supports. The target plates may be made of ceramic material or high melting-point material (e.g., ITO, zinc oxide, silicon or other ceramic, ceramic-like material). The tube magnetron designs can provide improved process uniformity in sputter coating operations, which is an essential condition for high coating layer quality on the substrate. The coating quality obtained by using tube targets with target plates in the inventive tube magnetrons can be superior to the coating quality obtained using conventional tube targets that have been coated with sputter material or consist of full material. The inventive tube magnetrons may be advantageously used for more variable and less costly coating processes compared to conventional coating processes using tube targets of like quality.

In exemplary tube magnetrons designs, the target plates are arranged adjacent to each other to form a polygon in cross section. The occurrence of surface regions without target material as inhomogeneous sections on the tube targets is thus avoided. This substantially reduces the irregular fluctuations of the magnetic field strength and of the sputter rate, which are produced due to alternating passage through the target plate surfaces and gaps between the plates free from sputter material by the magnetic fields of the magnet system.

In one exemplary tube magnetron design, the width and number of target plates is selected so that an angle α, which is enclosed by two imaginary radial lines each running through one corner of two adjacent corners of the polygon, is related to an angle β, which is enclosed by two imaginary radial lines running through the magnetic field maxima, as
β=(n+0.5) α, where n=0, 1, 2, 3, 4 . . .

In this way, the distance of each corner of the polygon from the central longitudinal line of a target plate is approximately equal to the distance between the magnetic field maxima in the region of the target plate surface.

A corner produces in the magnetic field maximum a comparatively small, areal or surface center—because of its fairly great proximity to the magnet system—a comparatively high sputter rate. Owing to the design, in each instance a corner passes through the one magnetic field maximum, while an areal center passes through the other magnetic field maximum. This results in a high sputter rate combined with a low sputter rate, in sum, an average sputter rate. Other sections on the polygon are related to one another in like fashion. Hence, peaks of the sputter rates are equalized in sum and fluctuations of the sputter rate, remaining despite the full-area arrangement of the target plates produced by the polygonal tube target surface, are further reduced.

In other words, upon passing through a location on the target surface having the greatest tube target radius “polygon corner” through the magnetic field, the magnetic field effect on the plasma space weakens and the sputter rate is reduced to a minimum, whereas passage through the location on the target surface having the smallest tube target radius (“polygon sink”) results in an increase in the magnetic field effect and the sputter rate increases to a maximum. This decrease and increase in the sputter rate upon passage through the magnetic fields is equalized by the uniformly repeating position of a “polygon peak” and a “polygon sink,” equal in time, in regions of the magnetic field of like intensity, preferably at its two maxima. Then, according to the distance between the magnetic field maxima and the width of the target plates in relation thereto, in each instance the longitudinal edge of the plate forming the polygon peaks and the central longitudinal line of any desired target plates forming the polygon sinks are combined together. This arrangement achieves the effect of damping the oscillating behavior of the sputter rate and thus process uniformity of new quality.

It is especially favorable to select the width and number of target plates so that
β=1.5 α.

In polygons with a variable number of corners, the following angles of the magnetic field maxima then result:

| | |
|---|---|
| In a hexagonal polygon: | β = 90° |
| In an octagonal polygon: | β = 67.5° |
| In a decagonal polygon: | β = 54° |
| In a dodecagonal polygon: | β = 45°, etc. |

These angles permit target plate widths that can be readily achieved technologically.

In a favorable embodiment of the invention, the target plates are cemented or bonded to the target support. This technology facilitates the adjacent placement of the target plates on the target tube and avoids fixing means, which result in an inhomogeneous surface structure of the tube target.

In an advantageous embodiment of the invention, the target plates consist of ceramics, for example of ITO, zinc oxide, silicon, and of other ceramic, ceramic-like and/or high melting-point material, which are hard to apply to a tube target by other methods.

In an additional embodiment of the invention, the tube targets are capable of rotation at a speed of 1 s-1 to 2 min-1. Suitable rotation mechanisms which may be conventional can be deployed for this purpose. Thus, the speed of the tube target can be optimally adjusted to target plates of various widths.

Lastly, in an application of the invention, it is provided that equalization of minimal fluctuations of the plasma or the sputter rate is effected by a voltage control or by a plasma emission monitor control.

Effective compensation of sputter rate fluctuation by the target plate arrangement according to the invention is further improved by this control.

An exemplary tube magnetron designed according to the foregoing design principles is shown in FIG. 1. In particular, FIG. 1 shows a cross section view through a tube target with target plates affixed and a magnet system lying within the tube magnetron.

The tube magnetron is equipped with a rotating tube target 1, which is comprised of a tubular target support 2, to which a plurality of individual longitudinally extended flat target plates 3 with applied sputter material, such as for example ITO, zinc oxide, silicon and other ceramic, ceramic-like and/or high melting-point material, are cemented or bonded on adjacent to each other. The tangential bearing of the flat target plates 3 on the tubular target support 2 forms a continuous but polygonal target surface with polygon corners 4 and polygon sinks 6 on the tube target 1.

Owing to their shape, the longitudinal edges 8 of the target plates 3 geometrically form the polygon corners 4 and the central longitudinal axis 9 of the target plates 3, and considered geometrically, the polygon sinks 6 of the target surface.

In the interior of the tube target 1 is found the stationary magnet system 10, which produces a magnetic field with two magnetic field maxima 11, which pass through the tube target 1 at a distance 12 dependent upon the shape of the magnet system 10. The maximum possible sputter rate is reached at the core zones of the magnetic field, i.e., approximately in the region of the two magnetic field maxima 11, outside of which the sputter rate decreases.

The width 7 of each target plate 3 and the number of target plates 3 is selected so that an angle ÿ, which is enclosed by two imaginary radial lines 13 and 14 each running through a corner of two adjacent corners 4 and 5 of the polygon, is related to an angle ÿ, which is enclosed by two imaginary radial lines 15 and 16 running through the magnetic field maxima 11, as
β=(n+0.5)α with n=1, i.e.
β=1.5 α

As a result, the distance of each longitudinal edge 8 of the target plates 3 from the central longitudinal axis 9 of the adjacent target plate is approximately equal to the distance 12 between the magnetic field maxima in the region of the target plate surface. There, two geometrically significant points (each polygon corner 4 and polygon sink 6) are simultaneously located during rotation of the tube target 1 in one of the two magnetic field maxima 11 in each instance. At the same time, the variations in sputter rate, which occur due to the variable radial distance of the tube target surface from the axis of rotation of the tube target 1 and hence from the stationary magnet system 10, are cancelled. If a number of magnetic fields are used, the arrangement should be undertaken in analogous fashion, so that the same number of polygon corners 4 and polygon sinks 6 are in the magnetic field maxima 11 equal in time.

1-7. (canceled)

8. A tube magnetron comprising:
a hollow rotating tube target arrangement of longitudinally extended target plates that are fixed to a target support, wherein the target plates in cross section are arranged adjacent to each other to form a polygon; and
a magnet system, wherein the magnet system provides a magnetic field passing through the tube target arrangement, wherein the magnetic field has in cross section two maxima arranged in the axial longitudinal direction of the tube target arrangement and in the interior thereof.

9. The tube magnetron of claim 8, wherein the width and number of target plates are selected so that an angle ÿ, which is enclosed by two imaginary radial lines each running through adjacent corners of the polygon, is related to an angle ÿ, which is enclosed by two imaginary radial lines running through the magnetic field maxima as =(n+0.5) a wherein n is select to be an integer (n=0, 1, 2, 3, 4 . . . ).

10. The tube magnetron of claim 9, wherein n selected to be 1 so that β=1.5 α.

11. The tube magnetron of claim 8 wherein the target plates are cemented or bonded to the target support.

12. The tube magnetron of claim 8 wherein the target plates comprise target material selected from the group of ceramic materials, ceramic-like materials, high melting-point materials and any combination thereof.

13. The tube magnetron of claim 12 wherein the target material comprises one of ITO, zinc oxide, and silicon.

14. The tube magnetron of claim 8 which is further configured so that the tube target rotates at a speed of about 1 revolution s-1 to about 2 revolutions min-1.

15. A tube magnetron for sputtering of target material by a plasma on application of a voltage, comprising:
a hollow rotating tube target arrangement of longitudinally extended target plates that are fixed to a target support; and
a magnet system configured to provide a magnetic field passing through the tube target arrangement,
wherein the target plates in cross section are arranged adjacent to each other to form a polygon, wherein the magnetic field has in cross section two maxima arranged in the axial longitudinal direction of the tube target arrangement, and wherein the tube magnetron is further configured so that in operation equalization of at least one of plasma fluctuations and sputter rate fluctuations is effected by at least one of an applied voltage control and a plasma emission monitor control.
